(19) United States
(12) Patent Application Publication
(10) Pub. No.: US 2024/0401238 A1
(43) Pub. Date: Dec. 5, 2024

(54) LAMINATE HAVING GROUP 13 ELEMENT NITRIDE SINGLE CRYSTAL SUBSTRATE

(71) Applicant: NGK INSULATORS, LTD., Nagoya-shi (JP)

(72) Inventors: Kentaro NONAKA, Gifu-shi (JP); Takahiro TAMURA, Kiyosu-shi (JP); Sota MAEHARA, Nagoya-shi (JP); Yoshitaka KURAOKA, Okazaki-shi (JP)

(21) Appl. No.: 18/797,959

(22) Filed: Aug. 8, 2024

Related U.S. Application Data
(63) Continuation of application No. PCT/JP2022/038407, filed on Oct. 14, 2022.

(30) Foreign Application Priority Data
Feb. 18, 2022 (JP) 2022-023826

(51) Int. Cl. C30B 29/68; C30B 19/02; C30B 29/40; H01L 29/20; H01L 29/205

(52) U.S. Cl. CPC C30B 29/68; C30B 29/403; C30B 29/406; C30B 19/02; H01L 29/2003; H01L 29/205

(57) ABSTRACT

A laminate includes a group 13 nitride single crystal substrate composed of a group 13 nitride single crystal and having a first main face and a second main face, a buffer layer provided on the first main face of the group 13 nitride single crystal substrate, a channel layer provided on the buffer layer and a barrier layer provided on the channel layer. The channel layer has a thickness of 700 nm or smaller, and the first main face of the group 13 nitride single crystal substrate has an off-angle of 0.4° or more and 1.0° or less.

### CROSS-REFERENCE TO RELATED APPLICATIONS

This application is a continuation application of PCT/JP2022/038407, filed Oct. 14, 2022, which claims priority to Japanese Application No. JP 2022-023826 filed on Feb. 18, 2022, the entire contents all of which are incorporated hereby by reference.

### TECHNICAL FIELD

The present invention is related to a laminate having a group 13 nitride single crystal substrate.

### BACKGROUND ART

Nitride semiconductor devices have been widely applied for optical devices as well as electronic devices such as a high electron mobility transistor (HEMT). For example, it is known an epitaxial substrate including a buffer layer, channel layer and barrier layer formed on a free-standing substrate composed of semi-insulating gallium nitride single crystal doped with zinc.

For example, according to patent document 1, it is disclosed that the thickness of a channel layer is made less than 500 nm in an HEMT structure on a silicon carbide substrate for suppressing leak current and current collapse.

Further, there is a problem that many defects are generated in gallium nitride film hetero-epitaxially grown on a substrate of a material of a different kind, due to the difference of lattice constants or thermal expansion coefficients of gallium nitride and the substrate of the material of the different kind. It has been thus studied the homo epitaxial growth of gallium nitride film on a gallium nitride substrate.

In the case that the gallium nitride substrate is applied, it is preferred to utilize the gallium nitride substrate of semi-insulating property for preventing leak current between electrodes of source-drain when an HEMT device is driven at a high voltage, and it is known effective to dope an element capable of forming deep acceptor level such as a transition metal element in gallium nitride single crystal for realizing the semi-insulating gallium nitride substrate. It is described in patent documents 2, 3 and 4 that zinc, manganese or iron is applied as such doping element.

According to patent documents 5 and 6, it is disclosed that a semi-insulating and free-standing gallium nitride substrate doped with zinc as an epitaxial substrate for an HEMT device.

### PRIOR TECHNICAL DOCUMENTS

### Patent Documents

(Patent document 1) Japanese patent publication No. 2021-002616A
(Patent document 2) Japanese patent No. 5039813B
(Patent document 3) Japanese patent publication No. 2006-024597A
(Patent document 4) Japanese patent publication No. 2007-534580A
(Patent document 5) Japanese patent No. 6730302B
(Patent document 6) Japanese patent No. 6705831B

### SUMMARY OF THE INVENTION

According to patent document 1, it is disclosed that the thickness of the channel layer is made less than 500 nm for preventing both of the leak current and current collapse in the HEMT structure on the silicon carbide substrate. In the case that the HEMT device is operated at a high frequency band of, for example, several tens GHz or higher, it is considered effective to make the film thickness of the channel layer smaller for preventing the deterioration of a property due to parasitic capacitance of the channel layer.

Then, as the inventors produced and evaluated an epitaxial substrate including the channel layer of the thin film on a group 13 nitride single crystal substrate for improving the property of the HEMT device, the problem is provided that characteristic indices of the high carrier density and carrier mobility were reduced.

An object of the present invention is to suppress the reduction of the sheet carrier density and carrier mobility, in a laminate including a buffer layer provided on a first main face of a group 13 nitride single crystal substrate, a channel layer provided on the buffer layer and having a thickness of 700 nm or smaller and a barrier layer provided on the channel layer.

The present invention provides a laminate comprising: a group 13 nitride single crystal substrate comprising a group 13 nitride single crystal and having a first main face and a second main face;
a buffer layer provided on the first main face of the group 13 nitride single crystal substrate;
a channel layer provided on the buffer layer; and
a barrier layer provided on the channel layer,
wherein the channel layer has a thickness of 700 nm or smaller, and
wherein the first main face of the group 13 nitride single crystal has an off-angle of 0.4° to 1.0°.

The inventors found that the reduction of the sheet carrier density and carrier mobility can be suppressed in the laminate including the buffer layer provided on the first main face of the group 13 nitride single crystal substrate, the channel layer provided on the buffer layer and having a thickness of 700 nm or smaller and the barrier layer provided on the channel layer, and the present invention was thus made. Although the reason of such effects is not clear, the off-angle of the first main face of the group 13 nitride single crystal substrate is made 0.4° to 1.0° so that the surface flatness of the thinned channel layer is improved, and it is considered that the improvement contributes to the improvement of the sheet carrier density and carrier mobility.

### BRIEF DESCRIPTION OF THE DRAWINGS

FIG. 1A is a diagram schematically showing a laminate 1 according to an embodiment of the present invention, and FIG. 1B is a diagram schematically showing a composite substrate 8 for depositing an epitaxial growth layer.

FIG. 2A is a representative schematic and perspective view showing a group 13 nitride single crystal substrate 100 according to a preferred embodiment, and FIG. 2B is a diagram schematically illustrating the plane orientation and crystalline planes of crystalline structure of a group 13 nitride single crystal substrate according to a preferred embodiment.

FIG. 3 is a graph showing the dependency of the sheet carrier density of a channel layer on the off-angle of a zinc-doped group 13 nitride single crystal substrate.

FIG. 4 is a graph showing the carrier mobility of a channel layer on the off-angle of a zinc-doped group 13 nitride single crystal substrate.

FIG. 5 is a photograph showing the surface morphology of a channel layer in the case that the off-angle of the first main face of a zinc-doped group 13 nitride single crystal substrate is 0.66°.

FIG. 6 is a photograph showing the surface morphology of a channel layer in the case that the off-angle of the first main face of a zinc-doped group 13 nitride single crystal substrate is 0.09°.

FIG. 7 is a photograph showing the surface morphology of a channel layer in the case that the off-angle of the first main face of a zinc-doped group 13 nitride single crystal substrate is 1.150.

FIG. 8 is a graph showing an example of relationship of the off-angle of the first main face of a zinc-doped group 13 nitride single crystal substrate and carbon concentration of a channel layer.

### MODES FOR CARRYING OUT THE INVENTION

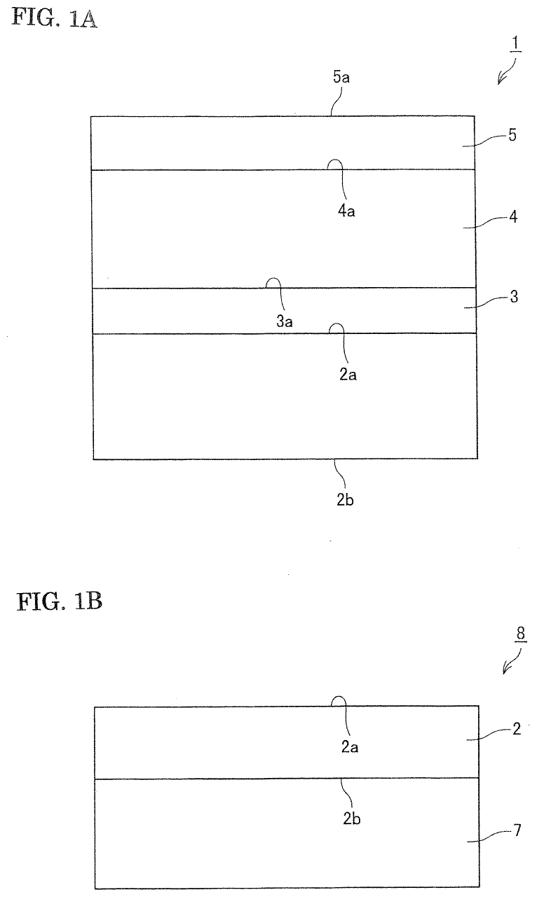

FIG. 1A is a diagram schematically showing a laminate 1 according to an embodiment of the present invention.

A group 13 nitride single crystal substrate 2 has a first main face 2a and second main face 2b. The first main face 2a of the group 13 nitride single crystal substrate 2 is selected as a film-forming face, and epitaxial growth layers are deposited on the first main face 2a. Specifically, according to the present invention, a buffer layer 3 is formed on the first main face 2a of the group 13 nitride single crystal substrate 2, a channel layer 4 is formed on the main face 3a of the buffer layer 3, and a barrier layer 5 is formed on the main face 4a of the channel layer 4. Predetermined electrode or the like may be formed on the main face 5a of the barrier layer 5.

A group 13 nitride single crystal substrate 2 is composed of a group 13 nitride single crystal and has a first main face 2a and second main face 2b.

The group 13 element is a group 13 element defined in IUPAC, and may particularly preferably be gallium, aluminum and/or indium. Further, the group 13 nitride single crystal may preferably be a group 13 nitride single crystal selected from gallium nitride, aluminum nitride, indium nitride or the mixed crystals thereof. More specifically, GaN, AlN, InN, GaₓAl₁₋ₓN (1>x>0), GaₓIn₁₋ₓN (1>x>0), AlₓIn₁₋ₓN (1>x>0) and GaₓAl_{y}In_{z}N (1>x>0, 1>y>0, x+y+z=1) are listed.

The definition of the single crystal will be described. Although it is included a single crystal, described in textbooks, in which atoms are regularly arranged over the whole of the crystal, it is not meant to be limited to only such mode and it is meant to include single crystals generally supplied in the industry. That is, the crystal may contain some degree of defects, or deformation may be inherent, or an impurity may be incorporated.

Further, the group 13 nitride single crystal substrate may be a free-standing substrate. The term “free-standing substrate” means a substrate that are not deformed or broken under its own weight during handling and can be handled as a solid. The free-standing substrate of the present invention can be used as a substrate for various types of semiconductor devices such as light emitting devices.

According to a preferred embodiment, the thickness of the free-standing substrate after the polishing may preferably be 300 μm or larger and preferably be 1000 μm or smaller.

Although the size of the free-standing substrate is not particularly limited, the size is preferably 2 inches, 4 inches or 6 inches and may be 8 inches or larger.

Further, as shown in FIG. 1B, an underlying substrate 7 composed of a material, whose thermal conductivity is higher than that of a group 13 nitride single crystal, is directly bonded to the side of the second main face 2b of the group 13 nitride single crystal substrate 2, so that a composite substrate 8 for depositing an epitaxial growth layer is obtained. The material of such underlying substrate may preferably be SiC, AlN or diamond. Further, the thermal conductivity of the underlying substrate may preferably be 200 W/mK or higher and more preferably be 500 W/mK or higher.

According to a preferred embodiment, the group 13 nitride single crystal contains one or two or more elements selected from the group consisting of zinc, manganese and iron as a dopant. On the viewpoint of the present invention, the total concentration of one or two or more elements selected from the group consisting of zinc, manganese and iron in the group 13 nitride single crystal substrate may preferably be 1×10¹⁸ atoms/cm³ to 1×10²¹ atoms/cm³ and more preferably be 1×10¹⁹ atoms/cm³ to 1×10²¹ atoms/cm³. Further, the concentrations of the elements in the group 13 nitride single crystal substrate is to be measured by SIMS (Secondary ion mass spectrometry).

Further, the group 13 nitride single crystal may contain an element in addition to the dopant. The element may be, for example, hydrogen (H), oxygen (O), silicon (Si) or the like.

The off-angle of the first main face of the group 13 nitride single crystal substrate is made 0.4° or more and 1.0° or less. Here, the standard axis of the off-angle may be a-axis, c-axis or m-axis of the Wurtzite structure.

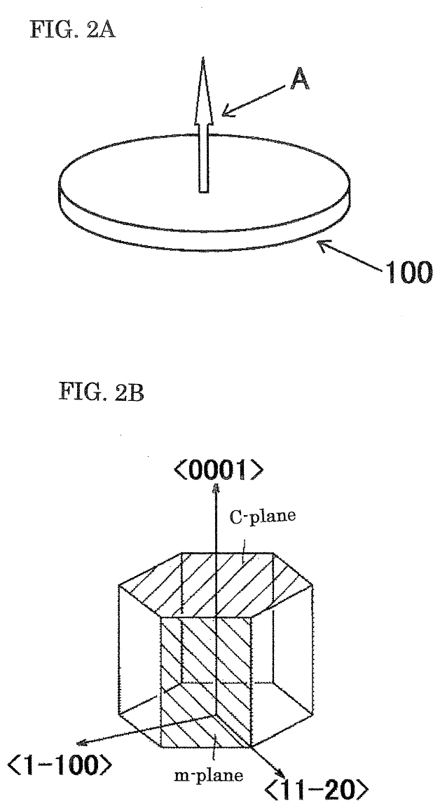

FIG. 2A is a representative and schematic perspective view showing a group 13 nitride single crystal substrate 100 according to a preferred embodiment. As shown in FIG. 2A, according to the group 13 nitride single crystal substrate 100 of the embodiment, the plane orientation <0001> (c axis) is inclined with respect to the normal vector A of the first face. That is, the group 13 nitride single crystal substrate 100 of the present embodiment is an off-angle substrate having an off-angle inclined with respect to the plane orientation <0001>.

FIG. 2B is a diagram schematically illustrating the plane orientation and crystal planes of the crystalline structure of the group 13 nitride single crystal substrate according to a preferred embodiment. In the crystalline structure shown in FIG. 2B, <0001> orientation is the orientation of the c-axis, <1-100> orientation is the orientation of the m-axis, and <11-20> orientation is the orientation of the a-axis. The upper face of the hexagonal crystal deemed as a regular hexagonal prism corresponds with the c-plane and the side wall face of the regular hexagonal prism corresponds with the m-plane.

According to the group 13 nitride single crystal substrate of the present embodiment, the c-plane is inclined with respect to the orientation of the first face. In other words, according to the group 13 nitride single crystal substrate of the present embodiment, the <0001> orientation (orientation of the c-axis) is inclined with respect to the normal vector of the first face (normal vector “A” shown in FIG. 2A). The direction of the inclination may be the in a-axis or m-axis.

By making the off-angle 0.4° or more, the reduction of the property of the channel layer can be suppressed even in the case that the channel layer is thinned, and particularly the reduction of the sheet carrier density and carrier mobility of secondary electron gas can be suppressed. On such viewpoint, the off-angle may more preferably be 0.5° or more. Further, in the case that the off-angle exceeds 1.0°, step bunching is generated in micro regions on the surface of the channel layer, and distortion at an interface of the channel layer, for example at an interface between barrier layer and channel layer, is changed so that the reduction of the property, particularly reduction of the sheet carrier density, is observed. On the viewpoint, the off-angle is made 1.0° or less, may preferably be made 0.9° or less, and more preferably be 0.7° or less on the viewpoint of both of the sheet carrier density and carrier mobility.

According to a preferred embodiment, the group 13 nitride single crystal substrate has a specific resistance at room temperature of 1×10⁷ Ωcm or higher. That is, the group 13 nitride single crystal substrate is of semi-insulating, so that it is effective to prevent the leak current between electrodes of source-drain in a semiconductor device, for example an HEMT device. On such viewpoint, the specific resistance at room temperature of the group 13 nitride single crystal substrate may more preferably be 1×10⁹ Ωcm or higher. Further, the specific resistance at room temperature of the group 13 nitride single crystal substrate is 1×10¹³ Ωcm or lower in many cases.

### (Production of Group 13 Nitride Single Crystal)

The method of producing the group 13 nitride single crystal substrate may be a vapor phase method such as Metal Organic Chemical Vapor Deposition (MOCVD) method, hydride vapor phase epitaxy (HVPE) method, pulse-excited deposition (PXD) method, MBE method, sublimation method or the like, or a liquid phase method such as ammonothermal method, flux method or the like. More preferably, the group 13 nitride single crystal is that produced by flux method.

In the case of flux method, it is preferred to provide a seed crystal film on the surface of a supporting substrate such as sapphire, a group 13 nitride single crystal or the like and to grow the group 13 nitride single crystal thereon by flux method.

AlxGa1-xN (0≤x≤1) or InxGa1-xN (0≤x≤1) may be listed as preferred examples as the material of the seed crystal film, and gallium nitride is particularly preferred.

The method of forming the seed crystal film may preferably be a vapor phase deposition method, and Metal Organic Chemical Vapor Deposition (MOCVD) method, hydride vapor phase deposition (HVPE) method, pulse-excited deposition (PXD) method, MBE method and sublimation method are listed. Metal Organic Chemical Vapor Deposition method is most preferred. Further, the growth temperature may preferably 950 to 1200° C.

In the case that the group 13 nitride single crystal is grown by flux method, the kind of the flux is not particularly limited, as far as the single crystal can be generated. According to a preferred embodiment, the flux contains at least one of an alkali metal and alkaline earth metal and the flux containing sodium metal is particularly preferred.

A raw material substance of a metal is mixed with the flux and applied. The raw material substrate of a metal may be a single metal, alloy or metal compound, and the single metal is preferred on the viewpoint of handling.

The growth temperature and holding time for the growth of the group 13 nitride single crystal by flux method are not particularly limited and may be appropriately changed depending on the composition of the flux. For example, in the case that gallium nitride crystal is grown by applying the flux containing sodium or lithium, the growth temperature may preferably be 800 to 950° C. and more preferably be 850 to 900° C.

According to flux method, the group 13 nitride single crystal is grown under atmosphere containing a gas including nitrogen atom. The gas may preferably be nitrogen gas and may be ammonia. Although the pressure of the atmosphere is not particularly limited and may preferably be 10 atoms or higher and more preferably be 30 atoms or higher on the viewpoint of preventing the evaporation of the flux. However, as the pressure is higher, the scale of the system becomes larger. Thus, the total pressure of the atmosphere may preferably be 2000 atoms or lower and more preferably be 500 atoms or lower. Although the gas other than the gas including nitrogen atom in the atmosphere is not limited, an inert gas is preferred, and argon, helium or neon is particularly preferred.

According to a particularly preferred embodiment, an MOCVD-GaN template is mounted in a crucible, and 10 to 60 mass parts of Ga metal, 15 to 90 mass parts of Na metal, 0.1 to 5 mass parts of a total amount of one or more elements selected from the group consisting of zinc metal, manganese metal and iron metal and 10 to 500 mg of C are then filled in the crucible. The crucible is contained in a heating furnace, the temperature in the furnace is made 800° C. to 950° C., the pressure in the furnace is made 3 MPa to 5 MPa, the heating is performed for 20 hours to 400 hours and the temperature is then cooled to room temperature. After the termination of the cooling, the crucible is drawn out of the furnace.

The thus obtained gallium nitride single crystal is polished with diamond abrasives to flatten the surface. The gallium nitride single crystal is thereby formed on the MOCVD-GaN template.

### (Formation of Epitaxial Growth Layers)

According to the present invention, for example as shown in FIG. 1A, the respective epitaxial growth layers of a buffer layer 3, a channel layer 4 and barrier layer 5 are formed on a first main face 2a of a group 13 nitride single crystal substrate 2.

As the epitaxial growth layers grown on the group 13 nitride single crystal substrate, gallium nitride, aluminum nitride, indium nitride or the mixed crystals thereof are exemplified. Specifically, gallium nitride (GaN), aluminum nitride (AlN), indium nitride (InN), aluminum gallium nitride (GaₓAl₁₋ₓN) (1>x>0), indium gallium nitride (GaₓIn₁₋ₓN) (1>x>0), aluminum indium nitride (AlₓIn₁₋ₓN) (1>x>0) or aluminum indium gallium nitride (GaₓAl_{y}In_{z}N) (1>x>0, 1>y>0, x+y+z=1) are listed.

The formation of the buffer layer 3, channel layer 4 and barrier layer 5 can be performed by, for example, metal organic chemical vapor deposition (MOCVD) method. According the formation of the layers with MOCVD method, metal organic raw material gases (TMG (trimethyl gallium), TMA (trimethyl aluminum), TMI (trimethyl indium) or the like) depending on the target composition, ammonia gas, hydrogen gas and nitrogen gas are supplied into a reactor of an MOCVD furnace, and the group 13 nitride single crystals are subsequently generated by the vapor phase reaction of the metal organic raw material gases corresponding with the respective layers and ammonia gas while the group 13 nitride single crystal substrate mounted in the reactor is heated at a predetermined temperature.

It is possible to prevent the diffusion of a metal element doped into the group 13 nitride single crystal to the channel layer by the buffer layer.

According to a preferred embodiment, the buffer layer is composed of aluminum nitride or aluminum gallium nitride. As the composition of the buffer layer is made such composition having a high aluminum concentration, it is possible to further suppress the diffusion of the metal element into the channel layer. Further, the thickness of the buffer layer is made 1 nm or larger and 20 nm or smaller, so that it can be functioned as a back barrier for containing electrons of the channel layer and sheet carrier density and carrier mobility can be improved.

Preferred growth conditions of the buffer layer by MOCVD method are as follows.
Growth temperature: 700° C. to 1200° C.
Pressure in reactor: 5 kPa to 30 kPa
Carrier gas: Hydrogen
Ratio of nitrogen gas/group 13 element gas: 5000 to 20000
Ratio of raw material gas for aluminum/raw material gas for group 13 element: 0.7 to 1.0

The thickness of the channel layer is made 700 nm or smaller. It is thereby possible to prevent the reduction of a property due to the parasitic capacitance of the channel layer. On the viewpoint, the thickness of the channel layer may preferably be 500 nm or smaller and more preferably be 300 nm or smaller. Further, the thickness of the channel layer may preferably be 50 nm or larger.

According to a preferred embodiment, the channel layer is composed of gallium nitride.

Further, according to a preferred embodiment, it is preferred that carbon contained in the epitaxial growth layer is lower. In this case, the carbon concentration of the epitaxial growth layer may preferably be 5×10¹⁶ atom/cm³ or lower and more preferably be 2×10¹⁶ atom/cm³ or lower. Further, the carbon concentration of the epitaxial growth layer is to be measured by SIMS (Secondary ion mass spectroscopy).

According to a preferred embodiment, in the case that the channel layer is grown by MOCVD on the group 13 nitride single crystal substrate whose first main face has an off-angle of 0.4 to 1.0°, the growth temperature is made 1000° C. or lower and the growth rate is made 1 μm/hour or less. The growth temperature is made 1000° C. or lower, so that the diffusion of the metal element doped in the group 13 nitride single crystal substrate into the channel layer is suppressed and the reduction of the sheet carrier density and carrier mobility are suppressed in the case that the channel layer is thinned.

That is, in the case that the channel layer is thinned, it is studied the method of preventing the increase of the resistance and deterioration of crystallinity of the channel layer due to diffusion and contamination of the doping element, particularly Zn, Fe or Mn, of the group 13 nitride single crystal substrate into the channel layer. As a result, it is found that the diffusion of the doping element into the channel layer can be suppressed and high crystallinity can be obtained, by making the growth temperature of the channel layer 1000° C. or lower and growth rate 1 μm/hour or less. Although it is concerned the deterioration of the surface flatness or the increase of the carbon concentration of the channel layer when the channel layer is grown at 1000° C. or lower, the high surface flatness can be obtained by making the growth rate 1 μm/hour or less and the off-angle of the first main face of the group 13 nitride single crystal substrate 0.4° or more. According to a preferred embodiment, it is possible to obtain a carbon concentration of 2×10¹⁶/cm³ or lower.

On such viewpoint, the growth temperature of the channel layer may preferably be 990° C. or lower. Further, the growth temperature of the channel layer may preferably be 950° C. or higher. As the growth temperature is 950° C. or lower, pits tend to be generated on the surface of the epitaxial growth layer. The growth temperature may preferably be made 960° C. or higher.

On the viewpoint described above, the growth rate of the channel layer may more preferably be 0.8 μm/hour or less. Further, the growth rate of the channel layer may preferably be 0.3 μm/hour or higher and more preferably be 0.5 μm/hour or higher. As it is less than 0.3 μm/hour, the surface flatness of the channel layer tends to be deteriorated.

Preferred production conditions of the channel layer are as follows.
Growth temperature: as described above
Pressure in reactor: 30 kPa to 105 kPa
Carrier gas: Hydrogen
Ratio of nitrogen gas/gas for group 13 element: 1000 to 10000

According to a preferred embodiment, the barrier layer is composed of indium aluminum gallium nitride, indium aluminum nitride or aluminum gallium nitride.

In the case that the barrier layer is formed with aluminum gallium nitride by MOCVD, the following production conditions are preferred.
Growth temperature: 1000° C. to 1200° C.
Pressure in reactor: 1 kPa to 30 kPa
Ratio of nitrogen gas/raw material gas for group 13 element: 5000 to 20000
Carrier gas: Hydrogen
Ratio of raw material gas for aluminum/raw material gas for group 13 element: 0.1 to 0.4

In the case that the barrier layer composed of aluminum indium nitride is formed by MOCVD, the following production conditions are preferred.
Growth temperature: 700° C. to 900° C.
Pressure in reactor: 1 kPa to 30 kPa
Ratio of nitrogen gas/raw material gas for group 13 element: 2000 to 20000
Carrier gas: Nitrogen
Ratio of raw material gas for indium/raw material gas for group 13 element: 0.1 to 0.9

In the case that the barrier layer composed of aluminum indium gallium nitride is formed by MOCVD, the following production conditions are preferred.
Growth temperature: 700° C. to 1000° C.
Pressure in reactor: 1 kPa to 30 kPa
Ratio of nitrogen gas/raw material gas for group 13 element: 2000 to 20000
Carrier gas: Nitrogen
Raw material gas for aluminum/Raw material gas for group 13 element: 0.1 to 0.9
Raw material gas for indium/Raw material gas for group 13 element: 0.1 to 0.9

### EXAMPLES

### (Experiment A)

### (Production of Zinc-Doped Gallium Nitride Single Crystal Substrate)

### Production of GaN Template

A seed crystal film having a thickness of 2 μm and composed of gallium nitride was deposited by MOCVD method on a surface of a c-plane sapphire substrate having a diameter of 2 inches, to obtain an MOCVD-GaN template which can be applied as a seed crystal substrate. At this time, the off-angle of the c-plane sapphire substrate was appropriately adjusted, so that the off-angle of the deposition face of the MOCVD-GaN template was made 0 to 1.2°, to produce a plurality of the GaN templates having the different off-angles of the deposition faces.

### Formation of Zinc-Doped Gallium Nitride Single Crystal by Flux Method

By applying a plurality of the thus obtained MOCVD GaN templates as the seed crystal substrates and Na flux method, zinc-doped gallium nitride single crystals were formed. Specifically, gallium metal and sodium metal were filled as raw materials and powdery zinc was filled as a dopant in an alumina crucible, respectively, and the crucible was closed with an alumina lid. The ratio of gallium metal and sodium metal was adjusted at Ga/(Ga+Na) (mol %) of 15 mol %. The crucible was contained in a heating furnace, the temperature in the furnace was made 850° C., the pressure in the furnace was made 4.5 MPa, and the heating was performed over 100 hours, followed by cooling to room temperature. After the termination of cooling, the alumina crucible was drawn out of the furnace to prove that gallium nitride single crystal was deposited in a thickness of about 1000 μm on the surface of the seed crystal substrate.

### Flattening of Surface

The thus obtained gallium nitride single crystal was polished with diamond abrasives so that the surface is flattened and the total thickness of the gallium nitride single crystal formed on the c-plane substrate was made 700 μm. GaN single crystal was thereby formed on the MOCVD-GaN template. As the thus obtained underlying substrate and gallium nitride single crystal were observed by eyes, cracks were not confirmed in all of them.

### Separation of Seed Crystal Substrate

The seed crystal substrate was separated from the gallium nitride single crystal by laser lift-off method to obtain a gallium nitride single crystal substrate.

### Processing of Wafer

The first main face and second main face of the gallium nitride single crystal substrate were subjected to polishing treatment to obtain a zinc-doped gallium nitride single crystal substrate having a thickness of 400 μm.

### Measurement of Specific Resistance

As the specific resistance of the zinc-doped gallium nitride single crystal substrate was measured by electrical capacitance method, it was obtained a value of 5×10⁷ to 2×10¹¹ Ωcm.

### Formation of Epitaxial Growth Layers

The buffer layer 3, channel layer 4 and barrier layer 5 were grown on the first main face 2a of the zinc-doped gallium nitride single crystal substrate 2 by MOCVD to produce the laminate 1. As to the formation of the layers by MOCVD, in the case that the buffer layer is formed by aluminum nitride or aluminum gallium nitride, the channel layer is formed by gallium nitride and the barrier layer is formed by aluminum gallium nitride, it is applied an MOCVD furnace that the respective organic metal (MO) raw material gases of gallium and aluminum (trimethyl gallium (TMG): trimethyl aluminum (TMA)), ammonia gas, hydrogen gas and nitrogen gas can be supplied into a reactor, zinc-doped gallium nitride single crystal substrate mounted in the reactor is heated at a predetermined temperature, and gallium nitride crystal and aluminum gallium nitride crystal are generated by vapor phase reaction of ammonia gas and the organic metal raw material gases corresponding with the respective layers and sequentially deposited on the free-standing substrate. In the case that the barrier layer is composed of aluminum indium nitride or aluminum indium gallium nitride, organic metal raw material gas (trimethyl indium) containing indium is further applied.

Specifically, the following production conditions are applied.

### (Buffer Layer: AlN)

Growth temperature: 980° C.
Pressure in reactor: 5 kPa
Ratio of gas for group 15/gas for group 13: 15000
Al raw material gas/raw material gas for group 13: 1.0
Thickness: 20 nm

### (Channel Layer: GaN)

Growth temperature: 980° C.
Pressure in reactor: 100 kPa
Ratio of gas for group 15/gas for group 13: 6800
Growth rate: 0.7 μm/hour
Thickness: 200 nm

### (Barrier Layer: AlGaN)

Growth temperature: 1050° C.
Pressure in reactor: 5 kPa
Ratio of gas for group 15/gas for group 13: 12000
Ratio of Al raw material gas/raw material gas for group 13 element: 0.25
Thickness: 25 nm

### Production of Device for Measuring Hall Effect

It was produced a device for measuring the sheet carrier density and carrier mobility of the thus obtained epitaxial substrate for a semiconductor device. As the measuring device, a plurality of chips each having a square of 6 mm was cut out from the epitaxial substrate for a semiconductor device, and ohmic electrodes were formed near the ends at the four corners of the chip. 1 mm square of pattern composed of Ti/Al/Ni/Au was formed by vacuum vapor deposition method and photolithography as the electrode to provide the device for Hall measurement. The respective thicknesses of the metal layers of Ti, Al, Ni and Au may preferably be made in a range of 5 nm to 50 nm, a range of 40 nm to 400 nm, a range of 4 nm to 40 nm and a range of 20 nm to 200 nm in the order. Thereafter, it is preferred to perform heat treatment at 600° C. to 1000° C. under nitrogen atmosphere for 10 seconds to 1000 second, for improving the ohmic property of a source electrode and drain electrode.

### Measurement of Sheet Carrier Density and Carrier Mobility

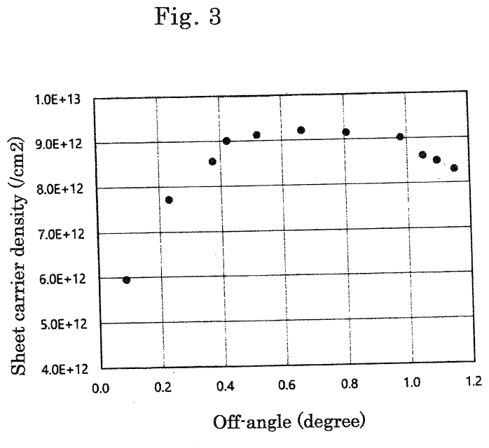

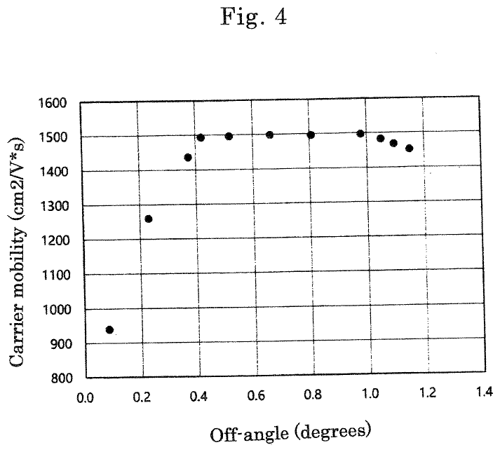

The sheet carrier density and carrier mobility at room temperature of the epitaxial growth layer of the thus produced device for Hall measurement were measured with Hall effect measurement (van der Pauw method). The Hall measurement effect was measured with a Hall effect measuring system (“ResiTest 8300” produced by TOYO Corporation). The measurement results are shown in table 1. Further, FIG. 3 shows the relationship of the off-angle and sheet carrier density, and FIG. 4 shows the relationship of the off-angle and carrier mobility.

Based on the Al composition and film thickness of the barrier layer studied according to the present embodiment, a sheet carrier density of 8.5×10¹²/cm³ or higher and an electron mobility of 1400 cm²/Vs or higher are considered to be good.

### Measurement of Off-Angle

For investigating the relationship of the sheet carrier density, carrier mobility and off-angle, the off-angle of the first main face of the zinc-doped gallium nitride single crystal substrate of the Hall measurement device was measured by X-ray diffraction method. The X-ray diffraction measurement was performed by a multi-purpose X-ray diffraction system (“D8 DISCOVER” produced by Bruker AXS Corporation). The results of measurement of the respective examples were shown in table 1.

Further, the relationship of the off-angle and sheet carrier density was shown in FIG. 3, and the relationship of the off-angle and carrier mobility was shown in FIG. 4.

TABLE 1

| | Off-angle of | | Carrier |
|---|---|---|---|
| | substrate | Sheet carrier | mobility |
| | [degree] | density [/cm²] | [cm²/V*s] |
| Comparative | 1.15 | 8.30E+12 | 1452 |
| Example | | | |
| Comparative | 1.09 | 8.49E+12 | 1468 |
| Example | | | |
| Comparative | 1.05 | 8.61E+12 | 1482 |
| Example | | | |
| Inventive | 0.98 | 9.02E+12 | 1497 |
| Example | | | |
| Inventive | 0.81 | 9.15E+12 | 1495 |
| Example | | | |
| Inventive | 0.66 | 9.22E+12 | 1498 |
| Example | | | |
| Inventive | 0.52 | 9.13E+12 | 1496 |
| Example | | | |
| Inventive | 0.42 | 9.01E+12 | 1493 |
| Example | | | |
| Comparative | 0.37 | 8.56E+12 | 1437 |
| Example | | | |
| Comparative | 0.23 | 7.72E+12 | 1259 |
| Example | | | |
| Comparative | 0.09 | 5.95E+12 | 940 |
| Example | | | |

As can be seen from table 1, in the case that the off-angle of the first main face (epitaxial growth face) of the zinc-doped gallium nitride single crystal substrate is in a range of 0.4 to 1.0°, the sheet carrier density and carrier mobility are proved to be high. On the contrary, in the case that the off-angle of the first main face of the zinc-doped gallium nitride single crystal substrate is less than 0.4° or more than 1.0°, the sheet carrier density and carrier mobility are proved to be lower.

### Evaluation of Surface Morphology

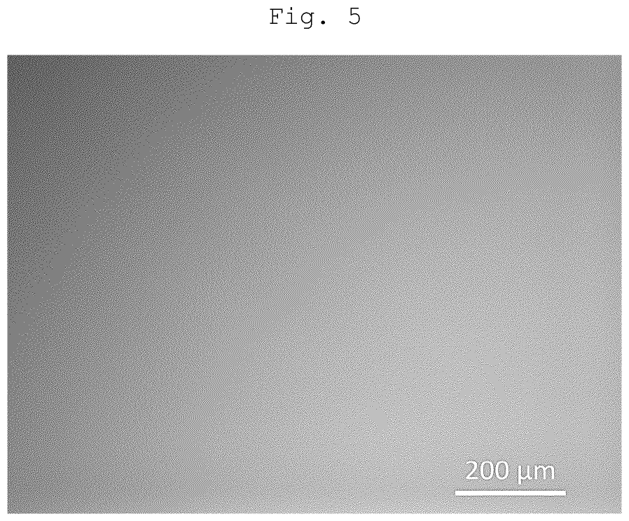

The surface morphology of the epitaxial growth layer was evaluated by an infinite interference optical microscope (“DM8000M” produced by LEICA Corporation). The magnification of observation was made 100 folds. As a result, according to the inventive examples in which the off-angle of the first main face 2a of the zinc-doped gallium nitride single crystal substrate 2 was 0.4° to 1.0°, good surface morphology with small roughness of the surface of the channel layer was confirmed. For example, FIG. 5 shows the surface morphology of the channel layer in the case that the off-angle of the first main face of the zinc-doped group 13 nitride single crystal substrate was 0.66°, and smooth surface morphology with small roughness can be observed.

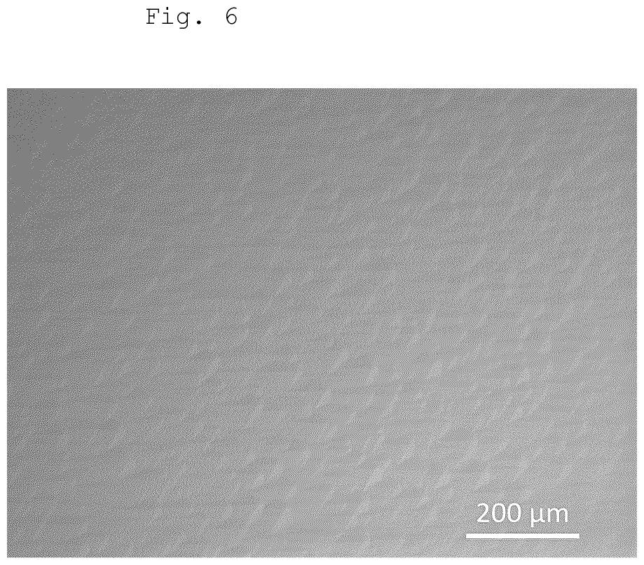

On the other hand, according to the comparative examples in which the off-angles were out of the range, the surface roughness of the channel layer was proved to be large. That is, in the case that the off-angle is below 0.4°, it was observed the morphology in which many island-shaped fine protrusions are dispersed on the surface of the channel layer. For example, FIG. 6 shows the surface morphology of the channel layer in the case that the off-angle was 0.09°.

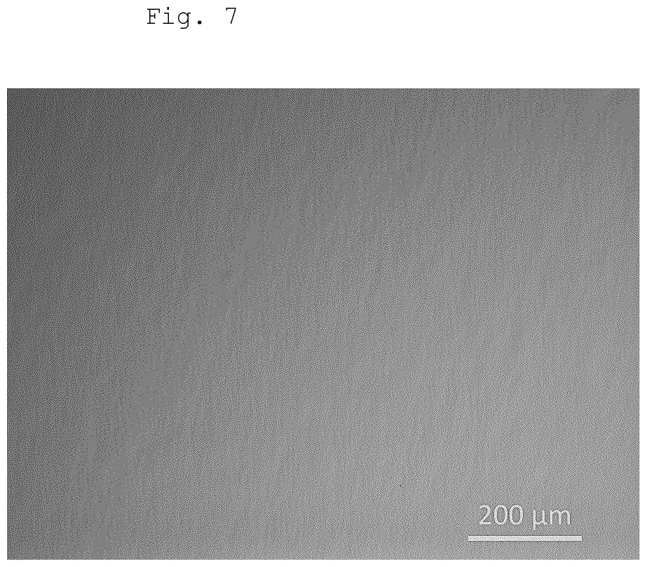

Further, in the case that the off-angle was large, so-called step bunching was generated. For example, FIG. 7 shows the surface morphology of the channel layer in the case that the off-angle is 1.15°, indicating that many fine and elongate steps are formed.

### Evaluation of Carbon Concentration of Channel Layer

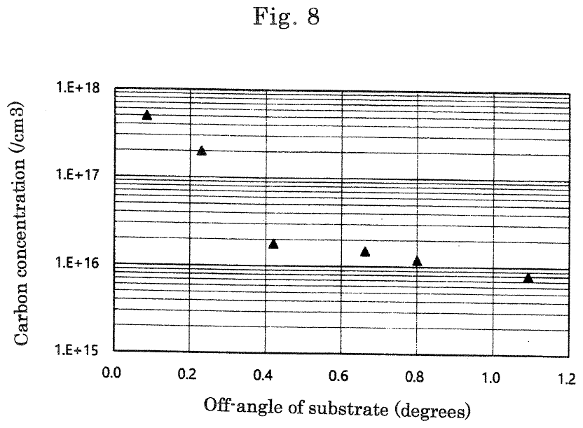

The carbon concentration of the channel layer was measured by SIMS. The results are shown in FIG. 8. According to the samples whose off-angles are 0.4° or more, the carbon concentration of the channel layer is proved to be 1×10¹⁶/cm³ or lower. On the other hand, in the sample whose off-angle is below 0.4°, it was observed an increase of carbon concentration of the channel layer.

### (Experiment B)

The off-angle described above was adjusted at 0.6° in the experiment A. Further, the thickness of the channel layer was changed to 1000 nm, 700 nm, 500 nm, 200 nm, 100 nm, 50 nm or 30 nm by adjusting the growth time period.

Then, the sheet carrier density and carrier mobility at room temperature of the channel layer were measured by Hall effect measurement (van der Pauw method). Further, the parasitic capacitance of the channel layer was measured by C-V method. Further, when the C-V method is performed, a shot-key electrode of p 1 cm was formed and the measurement frequency of 100 kHz was applied. The parasitic capacitance at application of −3V was measured and the results were shown in table 2.

TABLE 2

| Thickness of | Capacitance | Sheet carrier | Carrier mobility |
|---|---|---|---|
| channel layer (nm) | (pF) | density (/cm2) | (cm2/V*s) |
| 1000 | 1415 | 9.15E+12 | 1492 |
| 700 | 138 | 9.16E+12 | 1495 |
| 500 | 21.5 | 9.20E+12 | 1496 |
| 200 | 11.8 | 9.22E+12 | 1498 |
| 100 | 3.5 | 9.17E+12 | 1496 |
| 50 | 1.5 | 9.19E+12 | 1498 |
| 30 | 1.3 | 4.20E+12 | 853 |

As a result, in the case that the thickness of the channel layer is in a range of 50 nm to 700 nm, it is proved that the parasitic capacitance was reduced. At the same time, in the case that the thickness of the channel layer is in a range of 50 nm to 700 nm, the sheet carrier density and carrier mobility are good. In the case that thickness of the channel layer is 30 nm, the sheet carrier density is proved to be low. It is considered that the generation of carriers in 2DEG layer is suppressed.

### (Experiment C: Mn Doping)

Mn-doped gallium nitride single crystal substrates were grown according to the same conditions as those of the experiment A. However, the doping material added to the flux was changed to powdery manganese. As a result, a plurality of Mn-doped gallium nitride single crystal substrates having different off-angles were obtained. As the specific resistance at room temperature of the Mn-doped gallium nitride single crystal substrate was measured by electron capacitance system to obtain 8×10⁷ to 3×10¹¹ Ωcm.

Then, the buffer layer, channel layer and barrier layer were deposited on the first main face of the Mn-doped gallium nitride single crystal substrate, under the same conditions as those of the experiment A. The sheet carrier density and carrier mobility at room temperature of the channel layer were measured by Hall effect measurement (van der Pauw method). The results of the measurement were shown in table 3.

As a result, good results were obtained for the sheet carrier density and carrier mobility in the case that the off-angle was in a range of 0.4 to 1.0°.

TABLE 3

| | Off-angle of | | Carrier |
|---|---|---|---|
| | substrate | Sheet carrier | mobility |
| | [degree] | density [/cm2] | [cm2/V*s] |
| Comparative | 1.10 | 7.87E+12 | 1402 |
| Example | | | |
| Inventive | 0.95 | 8.59E+12 | 1445 |
| Example | | | |
| Inventive | 0.67 | 8.86E+12 | 1472 |
| Example | | | |
| Inventive | 0.50 | 8.74E+12 | 1469 |
| Example | | | |
| Inventive | 0.42 | 8.56E+12 | 1460 |
| Example | | | |
| Comparative | 0.36 | 8.00E+12 | 1370 |
| Example | | | |
| Comparative | 0.24 | 7.15E+12 | 1322 |
| Example | | | |

### (Experiment D: Fe Doping)

Fe-doped gallium nitride single crystal substrates were grown, according to the same conditions as those of the experiment A. However, the doping material added to the flux was changed to powdery iron. As a result, a plurality of the Fe-doped gallium nitride single crystal substrates having different off-angles were obtained. As the specific resistance at room temperature of the Fe-doped gallium nitride single crystal substrate was measured by electrical capacitance method, it was obtained a value of 1×10⁷ to 2×10⁹ Ωcm.

Then, the buffer layer, channel layer and barrier layer were deposited on the first main face of the Fe-doped gallium nitride single crystal substrate, according to the same conditions as those of the experiment A. The sheet carrier density and carrier mobility at room temperature of the epitaxial growth layer were measured by Hall effect measuring method (van der Pauw method). The results of the measurement were shown in table 4.

As a result, good results were obtained for the sheet carrier density and carrier mobility in the case that the off-angle is in a range of 0.4 to 1.0°.

TABLE 4

| | Off-angle of | | |
|---|---|---|---|
| | substrate | Sheet carrier | Carrier mobility |
| | [degree] | density [/cm2] | [cm2/V*s] |
| Comparative | 1.07 | 8.03E+12 | 1395 |
| Example | | | |
| Inventive | 0.92 | 8.32E+12 | 1422 |
| Example | | | |
| Inventive | 0.70 | 8.37E+12 | 1443 |
| Example | | | |
| Inventive | 0.63 | 8.40E+12 | 1440 |
| Example | | | |
| Inventive | 0.43 | 8.21E+12 | 1417 |
| Example | | | |
| Comparative | 0.33 | 7.62E+12 | 1328 |
| Example | | | |
| Comparative | 0.20 | 7.21E+12 | 1310 |
| Example | | | |

1. A laminate comprising:
a group 13 nitride single crystal substrate comprising a group 13 nitride single crystal and having a first main face and a second main face;
a buffer layer provided on said first main face of said group 13 nitride single crystal substrate;
a channel layer provided on said buffer layer; and
a barrier layer provided on said channel layer,
wherein said channel layer has a thickness of 700 nm or smaller, and
wherein said first main face of said group 13 nitride single crystal substrate has an off-angle of 0.4° or more and 1.0° or less.

2. The laminate of claim 1, wherein said group 13 nitride single crystal contains one or more elements selected from the group consisting of zinc, manganese and iron as a dopant.

3. The laminate of claim 1, wherein said group 13 nitride single crystal substrate has a specific resistance at room temperature of 1×10⁷ Ωcm or higher.

4. The laminate of claim 1, wherein said channel layer has a thickness of 50 nm or larger.

5. The laminate of claim 1, wherein said buffer layer comprises aluminum nitride or aluminum gallium nitride.

6. The laminate of claim 1, wherein said buffer layer has a thickness of 1 nm or larger and 20 nm or smaller, and wherein said buffer layer comprises aluminum nitride or aluminum gallium nitride.

7. The laminate of claim 1, wherein said channel layer has a carbon concentration of 2×10¹⁶/cm³ or lower.

8. The laminate of claim 1, wherein said barrier layer comprises indium aluminum gallium nitride, indium aluminum nitride or aluminum gallium nitride.

9. The laminate of claim 1, wherein said channel layer comprises gallium nitride.

10. The laminate of claim 1, wherein said first main face has said off-angle of 0.5° or more and 0.7° or less.

11. The laminate of claim 1, wherein said group 13 nitride single crystal is produced by flux method.
